(19) United States
(12) Patent Application Publication
(10) Pub. No.: US 2026/0160814 A1
(43) Pub. Date: Jun. 11, 2026

(54) BATTERY DETERIORATION ESTIMATION METHOD

(71) Applicant: TOYOTA JIDOSHA KABUSHIKI KAISHA, Toyota-shi (JP)

(72) Inventors: Masaaki INOUE, Tokyo (JP); Hideaki BUNAZAWA, Tokyo (JP); Shintaro FUKUSHIMA, Tokyo (JP); Masanori OKAMOTO, Tokyo (JP)

(73) Assignee: TOYOTA JIDOSHA KABUSHIKI KAISHA, Toyota-shi (JP)

(21) Appl. No.: 19/384,860

(22) Filed: Nov. 10, 2025

(30) Foreign Application Priority Data
Dec. 11, 2024 (JP) 2024-216902

(51) Int. Cl. G01R 31/367; B60L 58/16; G01R 31/382; G01R 31/392

(52) U.S. Cl. CPC G01R 31/367; B60L 58/16; G01R 31/382; G01R 31/392

(57) ABSTRACT

A battery deterioration estimation method according to the present disclosure is a battery deterioration estimation method for a battery that is installed in a vehicle and supplies power to a motor, and includes processing of performing weighting of deterioration level performance data of the battery that is accumulated in advance, by performing weighting in accordance with similarity as to supplementary information regarding an estimation object battery, generating a trained model that takes usage history information of the battery as input and outputs deterioration level of the battery, by performing machine learning regarding the deterioration level performance data weighted in the processing as training data, and estimating the deterioration level of the estimation object battery using the trained model, based on the usage history information regarding the estimation object battery.

### CROSS-REFERENCE TO RELATED APPLICATION

This application claims priority to Japanese Patent Application No. 2024-216902 filed on Dec. 11, 2024. The disclosure of the above-identified application, including the specification, drawings, and claims, is incorporated by reference herein in its entirety.

### BACKGROUND

### 1. Technical Field

The present disclosure relates to a battery deterioration estimation method.

### 2. Description of Related Art

Japanese Patent Application Publication No. 2013-089424 (JP 2013-089424 A) discloses a deterioration level (state of health (SOH)) estimation model for secondary batteries based on physical and chemical characteristics of battery deterioration, such as deterioration behavior of electrodes according to the Arrhenius equation, the square root law of deterioration over time, and so forth.

### SUMMARY

The deterioration level estimation model for secondary batteries disclosed in JP 2013-089424 A takes, as input, usage history information regarding a secondary battery, such as elapsed time, amount of current flowing, and charging rate (State of Charge (SOC)) of the secondary battery, and outputs the deterioration level of the secondary battery. The inventors discovered that estimation precision of a deterioration level estimation model can be improved by using additional parameters, such as environment to which the battery (secondary battery) is exposed, and driving operations of a vehicle in which the battery is installed. However, when parameters are directly added to the deterioration level estimation model for secondary batteries disclosed in JP 2013-089424 A, there is a concern that performance of the model that estimates the deterioration level based on physical and chemical deterioration characteristics cannot be ensured.

The present disclosure has been made in light of the above-described circumstances, and provides a battery deterioration estimation method that can improve estimation accuracy while ensuring performance of a model based on physical and chemical deterioration characteristics.

A battery deterioration estimation method according to an aspect of the present disclosure is a battery deterioration estimation method for a battery that is installed in a vehicle and supplies power to a motor, and includes
processing of performing weighting of deterioration level performance data of the battery that is accumulated in advance, by performing weighting in accordance with similarity as to supplementary information regarding an estimation object battery,
generating a trained model that takes usage history information of the battery as input and outputs deterioration level of the battery, by performing machine learning regarding the deterioration level performance data weighted in the processing as training data, and
estimating the deterioration level of the estimation object battery using the trained model, based on the usage history information regarding the estimation object battery.

According to the present disclosure, a battery deterioration estimation method can be provided that can improve estimation precision while ensuring performance of a model based on physical and chemical deterioration characteristics.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram illustrating a configuration of a battery deterioration estimation system according to an embodiment of the present disclosure;

FIG. 2A is a graph of state of health (SOH) over time for a battery according to the embodiment of the present disclosure;

FIG. 2B is time-series data of SOH of the battery according to the embodiment of the present disclosure;

FIG. 2C is an example of supplementary information regarding the battery according to the embodiment of the present disclosure;

FIG. 2D is an example of supplementary information regarding the battery according to the embodiment of the present disclosure;

FIG. 3A is an input/output flow diagram of an SOH estimation model according to the embodiment of the present disclosure;

FIG. 3B is a comparison diagram of the SOH estimation model according to the embodiment of the present disclosure, an existing SOH estimation model, and an SOH estimation model obtained by complicating the existing model;

FIG. 4A is a diagram of weighting based on dimensional compression according to similarity of supplementary information regarding the battery according to the embodiment of the present disclosure;

FIG. 4B is a diagram of rule-based weighting according to the similarity of supplementary information regarding the battery according to the embodiment of the present disclosure;

FIG. 5 is a flowchart of a battery deterioration estimation method according to the embodiment of the present disclosure; and

FIG. 6 is a diagram showing a method for updating a deterioration estimation model according to the embodiment of the present disclosure.

### DETAILED DESCRIPTION OF EMBODIMENTS

A specific embodiment of the present disclosure will be described in detail below with reference to the drawings. Note that the present disclosure is not limited to the following embodiment. Also, the following description and drawings have been simplified as appropriate, for clarity of description.

### Configuration of Battery Deterioration Estimation System

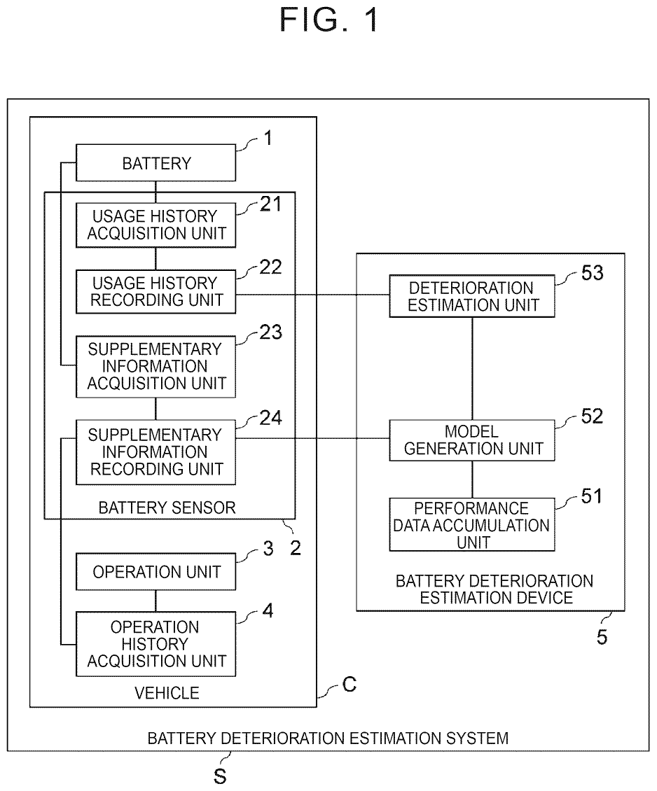

FIG. 1 is a block diagram illustrating a configuration of a battery deterioration estimation system according to an embodiment of the present disclosure.

The battery deterioration estimation system S is made up of a vehicle C and a battery deterioration estimation device 5. The vehicle C includes a battery 1, a battery sensor 2, an operation unit 3, and an operation history acquisition unit 4. The battery sensor 2 includes a usage history acquisition unit 21, a usage history recording unit 22, a supplementary information acquisition unit 23, and a supplementary information recording unit 24. The battery deterioration estimation device 5 includes a performance data accumulation unit 51, a model generation unit 52, and a deterioration estimation unit 53. Note that the battery 1 is an estimation object battery.

The vehicle C is a car that can travel by driving a motor (not shown) of the operation unit 3 under power supplied from the battery 1 to the operation unit 3. The vehicle C is, for example, a battery electric vehicle, but may be a hybrid electric vehicle having an external charging function, or the like, instead.

The battery 1 is connected to the usage history acquisition unit 21 and the supplementary information acquisition unit 23. The battery 1 is a power storage device that is installed in the vehicle C and has a function of supplying power to a drive unit that drives the vehicle C. The battery 1 is a secondary battery such as a lithium-ion battery, a lead storage battery, a nickel metal hydride battery, or the like, for example, and is configured by housing a cathode active material layer, an anode active material layer, a current collector, a separator, an electrolytic solution, and so forth, inside a sealing member. The battery 1 is connected to a motor that drives the vehicle C, thereby supplying power to this motor. The size of the battery 1 and the type of the secondary battery used for the battery 1 are decided as appropriate depending on the size and use of the vehicle C in which the battery 1 is to be installed.

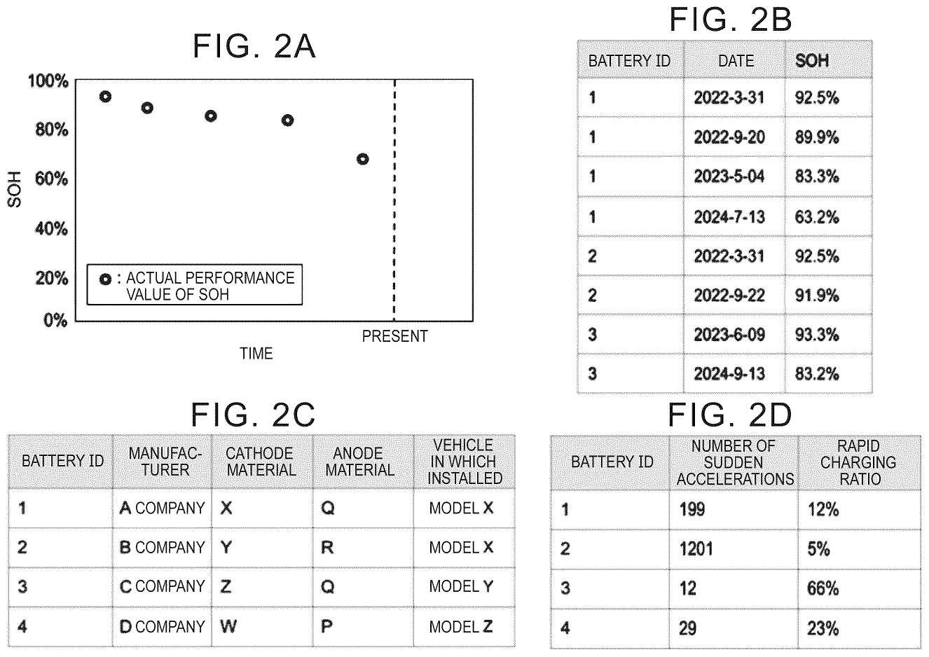

The battery sensor 2 is connected to the battery 1, the operation history acquisition unit 4, and the model generation unit 52. As shown in FIG. 2A for example, the battery sensor 2 acquires an SOH (State of Health) value of the battery 1 at a predetermined timing, and transmits the acquired results to the model generation unit 52. Here, the SOH is a ratio of the full charge capacity of the battery 1 when deteriorated, as to the full charge capacity of the battery 1 in an initial period, and is defined as

$$SOH ( \% ) = \frac{( full charge capacity of battery 1 when deteriorated )}{( full charge capacity of battery 1 in initial period )} \times 100 \qquad ( 1 )$$

In the present disclosure, the SOH found by Expression (1) is used as an index indicating the deterioration level of the battery 1. The smaller the SOH value is, this indicates that the deterioration of the battery 1 has progressed more, and the deterioration level of the battery 1 is greater.

The usage history acquisition unit 21 is connected to the battery 1 and the usage history recording unit 22. The usage history acquisition unit 21 acquires the SOH value of the battery 1 at a predetermined timing, and transmits the acquired data to the usage history recording unit 22. The usage history acquisition unit 21 includes, for example, sensors such as a current sensor, a voltage sensor, or the like, and acquires a current value or a voltage value at a predetermined timing. The usage history acquisition unit 21 calculates the SOH value of the battery 1 by finding the amount of current that flows from when the battery 1 is in an empty state to when in a fully-charged state, for example, based on the current value or the voltage value that is acquired. In order to calculate the SOH value of the battery 1, the usage history acquisition unit 21 may be made up of a central processing unit (CPU), a microprocessor unit (MPU), working memory, a non-volatile storage device that stores control programs, and so forth.

The usage history recording unit 22 is connected to the usage history acquisition unit 21 and the deterioration estimation unit 53. The usage history recording unit 22 records the SOH value of the battery 1 received from the usage history acquisition unit 21, and transmits the SOH value of the battery 1 that is recorded to the deterioration estimation unit 53. Note, however, that the usage history recording unit 22 may also record information regarding parameters that are used to find the SOH of the battery 1, such as the duration of current flowing and the amount of current flowing through the battery 1. That is to say, the usage history information regarding the battery 1 is the parameters used to find the SOH of the battery 1, such as the SOH value of the battery 1 at a predetermined timing, the duration of current flowing, the amount of current flowing, and so forth.

In the usage history recording unit 22, the SOH value of the battery 1 is recorded in the form of time-series data, as shown in FIG. 2B for example, as a battery ID assigned to each of the batteries, the date on which the SOH was recorded, and the recorded SOH value. The usage history recording unit 22 includes a storage device that can hold various types of data, and does not necessarily have to be part of the battery sensor 2 but rather may be an external storage device or cloud storage connected to the usage history 30 acquisition unit 21 via a network. The usage history recording unit 22 also includes a communication interface that can communicate with the deterioration estimation unit 53 via wired communication means, wireless communication means, or the like.

The supplementary information acquisition unit 23 is connected to the battery 1 and the supplementary information recording unit 24. The supplementary information acquisition unit 23 acquires supplementary information regarding the battery 1 and transmits the supplementary information regarding the battery 1 that is acquired to the supplementary information recording unit 24.

Here, examples of the supplementary information regarding the battery 1 may include
characteristic information regarding the battery 1, such as the full charge capacity of the battery 1 in the initial period, cathode material, anode material, material making up the electrolyte, the manufacturer, and so forth;
characteristic information regarding the vehicle C in which the battery 1 is installed, such as model, traveling performance, vehicle weight, and so forth, of the vehicle C;
history information regarding the traveling environment or vehicle state of the vehicle C in which the battery 1 is installed, such as the traveling region of the vehicle C, the SOC of the battery 1 during traveling, the battery temperature, the ambient temperature, and so forth;
history information regarding the driving operations and charging operations of the vehicle C in which the battery 1 is installed, such as the number of sudden accelerations and decelerations, the ratio of using rapid charging as to normal charging, and so forth;
and so on. Here, the characteristic information regarding the vehicle C is vehicle information regarding the vehicle C. Also, the traveling environment of the vehicle C, historical information regarding the vehicle state, and historical information regarding the driving operations and charging operations of the vehicle C, are traveling history information regarding the vehicle C. Also, the supplementary information acquisition unit 23 acquires information that can be obtained directly from the battery 1, such as the SOC of the battery 1 when traveling, the battery temperature, the ratio of using rapid charging as to normal charging, and so forth, as supplementary information regarding the battery 1.

The supplementary information acquisition unit 23 includes, for example, sensors such as a current sensor, a temperature sensor, or the like. Also, in order to acquire supplementary information regarding the battery 1 based on data such as current values, temperatures, or the like, acquired by the sensors, the supplementary information acquisition unit 23 may be made up of a CPU, an MPU, working memory, a non-volatile storage device that stores control programs, and so forth.

The supplementary information recording unit 24 is connected to the supplementary information acquisition unit 23, the operation history acquisition unit 4, and the model generation unit 52. The supplementary information recording unit 24 records the supplementary information regarding the battery 1 transmitted from the supplementary information acquisition unit 23 and the operation history acquisition unit 4, and transmits the recorded supplementary information regarding the battery 1 to the model generation unit 52.

The supplementary information recording unit 24 is a storage device that can hold various types of data, and does not necessarily have to be part of the battery sensor 2, but rather may be an external storage device or cloud storage connected to the usage history acquisition unit 21 via a network. The supplementary information recording unit 24 also includes a communication interface that can communicate with the deterioration estimation unit 53 via wired communication means, wireless communication means, or the like. Note that the usage history recording unit 22 and the supplementary information recording unit 24 may be the same storage device. Also, supplementary information regarding the battery 1, such as characteristic information regarding the battery 1 and characteristic information regarding the vehicle C in which the battery 1 is installed, may be recorded in advance in the supplementary information recording unit 24, or may be recorded by being transmitted from the supplementary information acquisition unit 23 and the operation history acquisition unit 4.

The operation unit 3 is connected to the operation history acquisition unit 4. The operation unit 3 is equipment for operating the vehicle C as a vehicle, such as, for example, a motor, brakes, a steering wheel, safety devices, an automotive navigation system, and so forth.

The operation history acquisition unit 4 is connected to the operation unit 3 and the supplementary information recording unit 24. The operation history acquisition unit 4 acquires operation history of the operation unit 3 and transmits the acquired data to the supplementary information recording unit 24 as supplementary information regarding the battery 1. The operation history acquisition unit 4 is equipped with sensors such as, for example, a speed sensor, a rotation speed sensor for the motor, a Global Positioning System (GPS) receiver, and so forth, and acquires information that can be acquired directly from the operation unit 3, such as the region in which the vehicle C is traveling, the number of sudden accelerations and decelerations, and so forth, as supplementary information regarding the battery 1.

The battery deterioration estimation device 5 is connected to the usage history recording unit 22 and the supplementary information recording unit 24. The battery deterioration estimation device 5 estimates the SOH based on the usage history information and the supplementary information regarding the battery 1, and performance value data and test data accumulated in the performance data accumulation unit 51, regarding a great number of batteries. Here, the SOH is estimated using an SOH estimation model that can estimate the SOH based on the physical and chemical characteristics of battery deterioration. The SOH estimation model will be described later.

The performance data accumulation unit 51 is connected to the model generation unit 52. The performance data accumulation unit 51 accumulates performance value data of used batteries that have been used in the past, and test data of batteries that have been tested, as deterioration level performance data. Here, the deterioration level performance data includes battery usage history information and supplementary information. The deterioration level performance data is training data that is necessary for the model generation unit 52 to generate an SOH estimation model, and is transmitted to the model generation unit 52 as needed. The performance data accumulation unit 51 includes a storage device that is capable of holding various types of data, and does not necessarily have to be part of the battery deterioration estimation device 5, but rather may be an external storage device or cloud storage connected to the model generation unit 52 via a network.

In the performance data accumulation unit 51, the supplementary information regarding the battery included in the deterioration level performance data is recorded in association with characteristic information regarding the battery and the vehicle C, such as battery ID, manufacturer, cathode material, anode material, and vehicle in which the battery is installed, as shown in FIG. 2C, for example. Also, the supplementary information regarding the battery, which is included in the deterioration level performance data, is recorded in association with battery ID, and history information regarding the vehicle C such as the number of sudden accelerations of the vehicle and the ratio of using rapid charging, as shown in FIG. 2D, for example.

The model generation unit 52 is connected to the supplementary information recording unit 24, the performance data accumulation unit 51, and the deterioration estimation unit 53. The model generation unit 52 generates an SOH estimation model, based on the supplementary information and deterioration level performance data of the battery 1, and transmits the model that is generated to the deterioration estimation unit 53. The model generation unit 52 is made up of, for example, a CPU, an MPU, working memory, a non-volatile storage device that stores control programs, and so forth. Also, the model generation unit 52 does not necessarily have to be a part of the battery deterioration estimation device 5, and an external cloud computing environment may be configured.

Here, an SOH estimation model f generated by the model generation unit 52 is, for example, an estimation model based on a square root law model relating to capacity retention rate y of the battery 1

$$y = - \sqrt{kt} + 1 \qquad ( 2 )$$

where k is a deterioration rate constant, and tis time. Also, the capacity retention rate y is the same as the value of SOH that is not expressed as a percentage. The value of k in Expression (2) is determined based on, for example, the Arrhenius equation

$$k = A \times exp ( - \frac{{E}_{a}}{RT} ) \qquad ( 3 )$$

where A is a frequency factor, Eₐ is activation energy for reaction, R is a gas constant, and T is temperature. By estimating A and Eₐ in Expression (3), the value of k at a certain temperature T can be estimated, and thus the SOH can be estimated. The parameters k, A, and Eₐ in Expressions (2) and (3) are parameter θ in the SOH estimation model f. That is to say, calculating the parameter θ enables estimation of the SOH by using the SOH estimation model f. Note that the SOH estimation model f may estimate the SOH using an expression based on physical and chemical characteristics of battery deterioration other than those described above, and as a result, the parameter θ may include parameters other than the above k, A, and Eₐ.

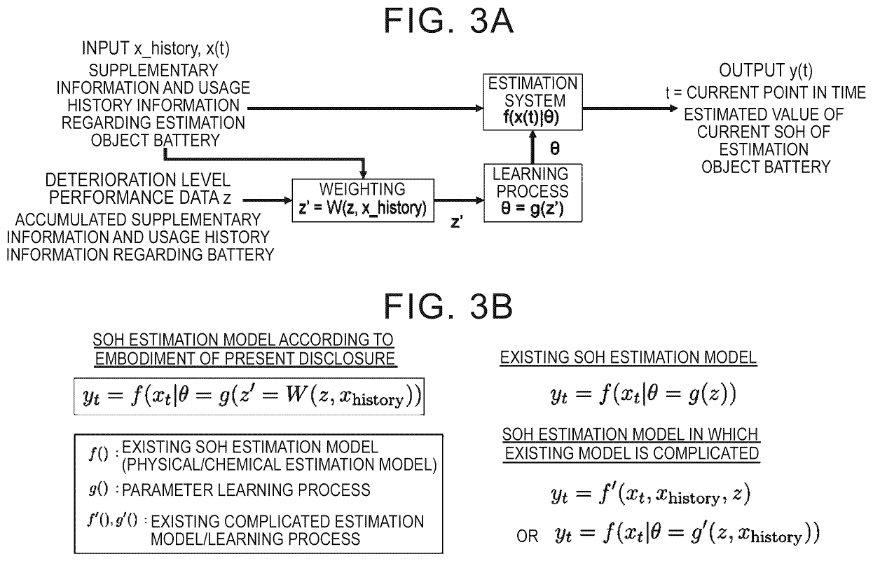

FIG. 3A is an input/output flow diagram of the SOH estimation model according to the embodiment of the present disclosure. In the SOH estimation model f, the parameter θ is estimated by using deterioration level performance data z as training data, and executing a parameter learning process g for learning the parameter θ. The SOH estimation model f generated by estimating the parameter θ is a trained model that takes usage history information x_t of the battery 1 as input, and outputs SOH value y_t of the battery 1. Here, the inventors discovered that by applying a weighting W to the performance data of each of the batteries included in the deterioration level performance data, in accordance with similarity with respect to supplementary information x_history of the battery 1, deterioration level performance data z′ that is consistent with the supplementary information x_history of the battery 1 can be generated. Using the deterioration level performance data z′ as training data when performing machine learning enables the estimation precision of the parameter θ to be improved and the performance of the SOH estimation model f to be improved.

FIG. 3B is a comparison of the SOH estimation model according to the embodiment of the present disclosure, an existing SOH estimation model, and an SOH estimation model obtained by complicating the existing model. In the SOH estimation model f according to the embodiment of the present disclosure, no change is made to the model structure or the parameter learning process g, but an improvement is made in that the deterioration level performance data that the parameter learning process g uses as training data is taken as z′. Accordingly, the precision of SOH estimation can be improved while ensuring the performance of the SOH estimation model f itself, which is based on the physical and chemical characteristics of battery deterioration.

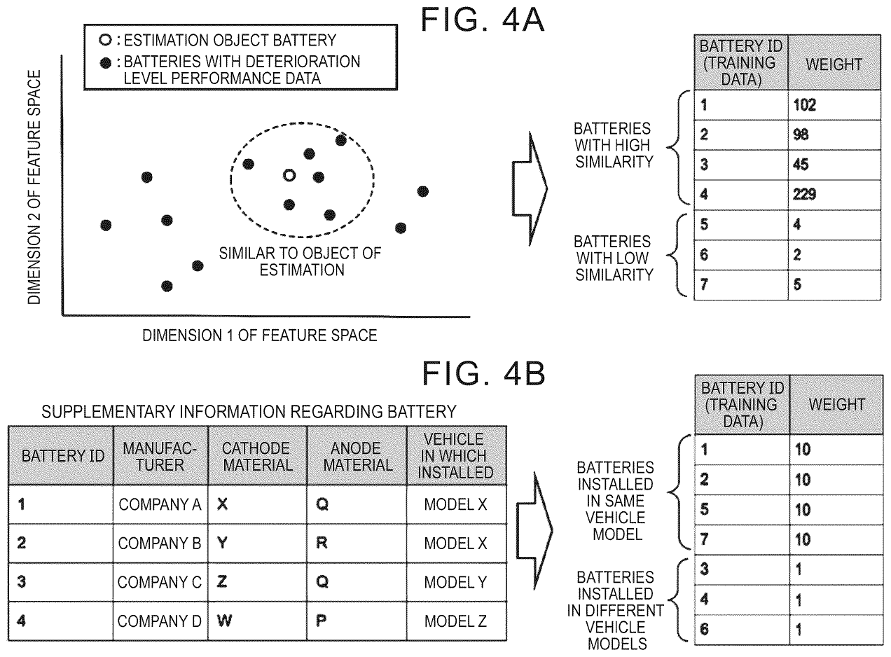

The weighting W of the deterioration level performance data z is performed by, for example, processing of increasing the weighting of the performance data of a battery having supplementary information that has a high level of similarity to the supplementary information regarding the battery 1. FIG. 4A is a diagram of weighting based on dimensional compression in accordance with similarity of the supplementary information regarding the battery according to the embodiment of the present disclosure. The weighting of the deterioration level performance data z is performed, for example, by performing dimensional compression on a set of supplementary information, and calculating feature vectors among batteries for supplementary information regarding the battery 1 that is the object of estimation, and the supplementary information regarding the battery, which is included in the deterioration level performance data. Similarity among batteries is calculated in accordance with the length of the feature vector, and weighting is performed in accordance with the similarity, thereby generating the deterioration level performance data z′ in which batteries having supplementary information similar to the supplementary information regarding the battery 1 are weighted more heavily.

Note, however, that the weighting of the deterioration level performance data z may be performed by rule-based weighting, as shown in FIG. 4B. In FIG. 4B, for example, vehicles equipped with batteries, which are vehicles in which batteries are installed, are compared, and a battery equipped in a vehicle of the same model as the vehicle C that is equipped with the battery 1 is weighted heavily. The same sort of weighting is performed based on each supplementary information, and the weighting values that are obtained for each of the batteries are summed up, for example, so as to generate deterioration level performance data z′ in which the batteries that have supplementary information similar to the supplementary information regarding the battery 1 are weighted more heavily.

The deterioration estimation unit 53 is connected to the usage history recording unit 22 and the model generation unit 52. The deterioration estimation unit 53 uses the SOH estimation model generated by the model generation unit 52 to estimate the SOH of the battery 1 based on the usage history information regarding the battery 1. The deterioration estimation unit 53 is made up of, for example, a CPU, an MPU, working memory, and a non-volatile storage device that stores control programs. Also, the deterioration estimation unit 53 does not necessarily have to be a part of the battery deterioration estimation device 5, and an external cloud computing environment may be configured. Furthermore, the model generation unit 52 and the deterioration estimation unit 53 may be configured using the same CPU, MPU, working memory, non-volatile storage device storing control programs, and so forth.

As described above, the battery deterioration estimation system according to the embodiment of the present disclosure generates new deterioration level performance data, in which increased weighting is applied to batteries that have a high level of similarity to the supplementary information regarding the estimation object battery, based on accumulated deterioration level performance data. In addition, performing machine learning using the generated deterioration level performance data as training data enables an SOH estimation model to be generated that is more consistent with the estimation object battery. This enables a battery deterioration estimation method to be provided that can improve estimation precision while ensuring performance of a model that is based on physical and chemical deterioration characteristics.

### Battery Deterioration Estimation Method

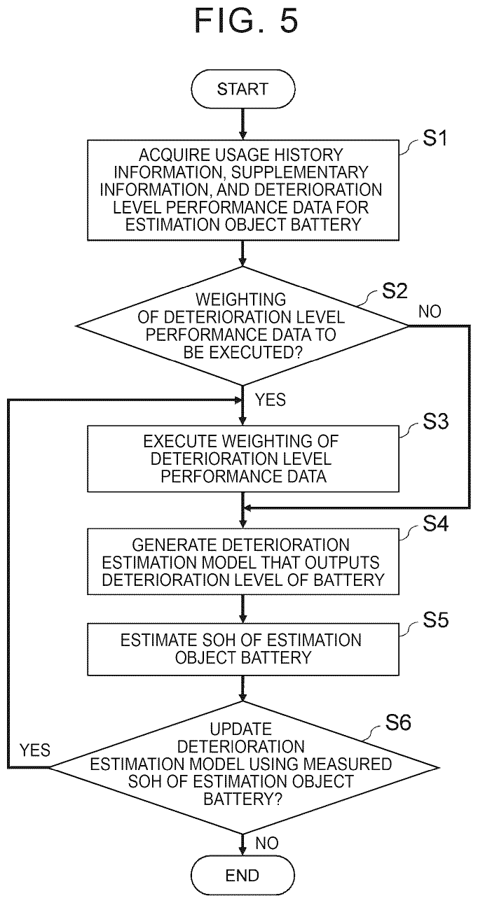

Next, the battery deterioration estimation method according to the embodiment of the present disclosure will be described with reference to FIG. 5. FIG. 5 is a flowchart of the battery deterioration estimation method according to the embodiment of the present disclosure.

First, the model generation unit 52 acquires the supplementary information and the deterioration level performance data of the battery 1, which is the estimation object battery, and the deterioration estimation unit 53 acquires the usage history information regarding the battery 1 (step S1). Note, however, that it is sufficient for the deterioration estimation unit 53 to acquire the usage history information regarding the battery 1 before the deterioration estimation unit 53 executes step S5 that will be described later.

Next, whether weighting should be applied to the deterioration level performance data z is decided (step S2). In step S2, for example, when the count of the deterioration level performance data z is excessively great with respect to the performance of the model generation unit 52, the model generation unit 52 does not perform weighting. Note, however, that depending on the performance of the model generation unit 52, weighting may be performed regarding only a portion of the deterioration level performance data z. A threshold value of the count of the deterioration level performance data z that is used to determine whether weighting should be performed is decided as appropriate in accordance with the performance of the model generation unit 52.

Also, when comparing the supplementary information regarding the battery 1 with the supplementary information regarding the batteries included in the deterioration level performance data z indicates that there are few batteries having supplementary information similar to the supplementary information regarding the battery 1, weighting based on the supplementary information is not performed in the rule-based weighting. For example, when the number of data items relating to batteries installed in vehicles similar to the vehicle C in which the battery 1 is installed is extremely small, weighting based on the vehicle in which the battery is installed is not performed. Note, however, that a threshold value for the number of batteries having supplementary information that is similar to the supplementary information of the battery 1 is decided as appropriate depending on the count of battery data included in the deterioration level performance data z.

When weighting is to be performed on the deterioration level performance data z (Yes in step S2), the model generation unit 52 performs weighting of the deterioration level performance data z (step S3). The weighting is performed as described above, and the deterioration level performance data z′ is generated with a higher weighting for batteries having supplementary information similar to the supplementary information of the battery 1. On the other hand, when weighting is not to be performed on the deterioration level performance data z (No in step S2), step S3 is not performed, and the deterioration level performance data z is used as training data unchanged.

Next, machine learning is performed using the deterioration level performance data z′ or z as training data, to generate a trained model as a deterioration estimation model (SOH estimation model) that takes battery usage history information as input and outputs the battery deterioration level (step S4). Here, when deterioration level performance data z′ that is consistent with the supplementary information regarding the battery 1 is used as training data, an SOH estimation model that is more suitable for estimating the SOH of the battery 1 is generated.

In step S4, machine learning is performed to reduce error between the SOH value output by the SOH estimation model f and the SOH performance values included in the deterioration level performance data z′, and the SOH estimation model f is generated. Here, the least squares method or the like, for example, may be used as an optimization technique for optimizing the parameter θ for generating the SOH estimation model f. Also, the parameter θ may be optimized by using artificial intelligence (AI), for example. When optimizing the parameter θ, the weighting values assigned to each deterioration level performance data in step S3 is used unchanged as the weighting at each deterioration level performance data point.

Subsequently, the deterioration estimation unit 53 estimates the SOH of the battery 1 using the deterioration estimation model generated in step S4 (step S5).

Finally, the actual SOH measurement value of the battery 1 is used to decide whether to update the deterioration estimation model generated in step S4 (step S6). When the deterioration estimation model is not to be updated (No in step S6), the processing ends. Note that the actual SOH measurement value data of the battery 1 may be stored in the deterioration level performance data, and processing may be performed to increase the number of samples of the deterioration level record data.

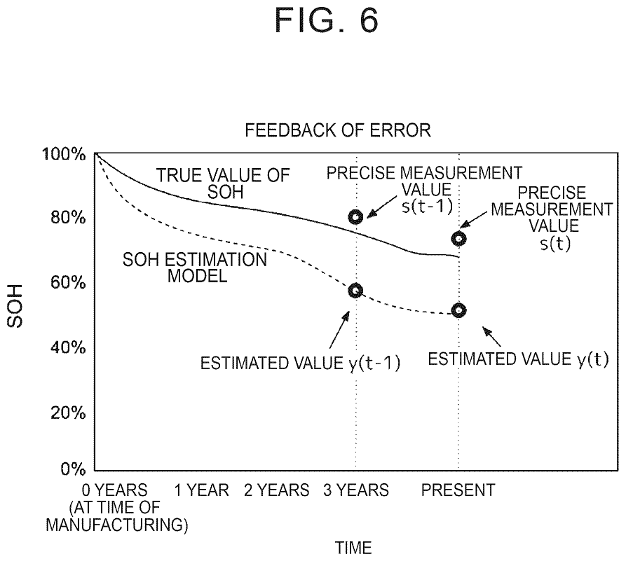

On the other hand, when the deterioration estimation model is to be updated (Yes in step S6), the actual SOH measurement value of the battery 1 is used, and the processing returns to step S3 to perform weighting of the deterioration level performance data and updating of the deterioration estimation model again. FIG. 6 is a diagram showing a method for updating the deterioration estimation model according to the embodiment of the present disclosure. Updating of the deterioration estimation model is performed, for example, by providing feedback to the deterioration estimation model such that an absolute value of error y(t)−s(t) between estimated value y(t) and precise SOH measurement value s(t) becomes smaller.

Now, feedback to the deterioration estimation model may be performed at all times, or may be performed just when the absolute value of the error y(t)−s(t) exceeds a threshold value. Also, when overestimation of the estimated value when estimating the SOH is not desired, for example, a positive threshold value may be set and feedback may be performed when the value of the error y(t)−s(t) is greater than the positive threshold value. On the other hand, when underestimation of the estimated value is not desired, a negative threshold value may be set and feedback may be performed when the value of the error y(t)−s(t) is smaller than the negative threshold value. Also, besides the SOH value itself, the threshold value may also be some other indicator, such as the proportion of the error y(t)−s(t) as to s(t) or the like.

As a method of executing feedback, steps S3 to S5 are repeatedly executed for s=[s(t_1), . . . , s(t_n)] obtained as an actual measurement value at one or more points in time, for example, such that an error index (e.g., |y−s| or the like) calculated from estimated output y=[y(t_1), . . . , y(t_n)] corresponding to each point in time is reduced to a predetermined value.

In the feedback, processing is executed in step S3, for example, by changing the similarity when performing weighting, by changing rule-based classification category when performing rule-based weighting, or the like. Also, in step S4, for example, processing is executed to change an optimization technique for the parameter θ when generating the deterioration estimation model, or to change initial values or random numbers given to the optimization technique in advance, or the like. Also, in step S5, for example, processing is executed such as reducing or adding input variables of the deterioration estimation model, or changing the combination of architectures of the model, or the like. Note that efficiency of feedback may be improved by causing artificial intelligence to execute the processing of these steps.

As described above, the battery deterioration estimation method according to the embodiment of the present disclosure generates an SOH estimation model using deterioration level performance data, which is weighted heavily for batteries that have a high level of similarity to the supplementary information regarding the estimation object battery, as training data. Also, the deterioration estimation model is updated by comparing the estimated SOH value that is estimated using the generated SOH estimation model with the actual SOH measurement value and providing feedback. This enables a battery deterioration estimation method to be provided that can improve estimation precision while ensuring performance of a model that is based on physical and chemical deterioration characteristics.

What is claimed is:

1. A battery deterioration estimation method for a battery that is installed in a vehicle and supplies power to a motor, the battery deterioration estimation method comprising:
processing of performing weighting of deterioration level performance data of the battery that is accumulated in advance, by performing weighting in accordance with similarity as to supplementary information regarding an estimation object battery;
generating a trained model that takes usage history information of the battery as input and outputs deterioration level of the battery, by performing machine learning regarding the deterioration level performance data weighted in the processing as training data; and
estimating the deterioration level of the estimation object battery using the trained model, based on the usage history information regarding the estimation object battery.

2. The battery deterioration estimation method according to claim 1, wherein the supplementary information regarding the estimation object battery includes both or one of vehicle information and traveling history information regarding the vehicle.

3. The battery deterioration estimation method according to claim 1, wherein, in the processing, processing is executed in which weighting is increased for the deterioration level performance data of which similarity as to the supplementary information regarding the estimation object battery is high.

4. The battery deterioration estimation method according to claim 1, wherein, in the processing, whether to execute weighting of the deterioration level performance data is decided in accordance with a count of the deterioration level performance data of which similarity as to the supplementary information regarding the estimation object battery is high.

5. The battery deterioration estimation method according to claim 1, further comprising:
measuring the deterioration level of the estimation object battery; and
updating the trained model by adding, to the training data, the deterioration level performance data of the estimation object battery measured in the measurement step.
